(19) United States
(12) Patent Application Publication
(10) Pub. No.: US 2010/0019309 A1
(43) Pub. Date: Jan. 28, 2010

(54) MULTI-LEVEL FLASH MEMORY STRUCTURE

(75) Inventors: LIH WEI LIN, Chiayi County (TW); WEI SHENG HSU, Yilan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/178,465

(22) Filed: Jul. 23, 2008

(51) Int. Cl. H01L 29/792

(52) U.S. Cl. 257/324; 257/E29.309

(57) ABSTRACT

A multi-level flash memory structure comprises a semiconductor substrate having a protrusion, a plurality of storage structures separated by the protrusion, a dielectric layer overlying the storage structures and the protrusion of the semiconductor substrate, a gate structure positioned on the dielectric layer, and several diffusion regions positioned at the sides of the protrusion. Each of the storage structures includes a charge-trapping site and an insulation structure isolating the charge-trapping site from the semiconductor substrate.

### BACKGROUND OF THE INVENTION

(A) Field of the Invention

The present invention relates to a multi-level flash memory structure and method for preparing the same, and more particularly, to a multi-level flash memory structure and method for preparing the same with the storage structures separated by a protrusion to prevent the storage structures from being merged as the size of the flash memory is reduced.

(B) Description of the Related Art

Flash memory has been widely applied to the data storage of digital products such as laptop computers, digital assistants, cell phones, digital cameras, digital recorders, and MP3 players. Current flash memory design commonly comprises a silicon-oxide-nitride-oxide-silicon (SONOS) structure, which is widely used in flash memory because it possesses the advantages of a thinner memory cell and a simpler fabrication process.

FIG. 21 shows a memory cell 100 described in U.S. Pat. No. 6,011,725. The memory cell 100 includes diffused source/drain regions 120A and 120B in a semiconductor substrate 110, a gate insulator 130 overlying the semiconductor substrate 110, and a gate 150 overlying the gate insulator 130. The gate insulator 130 has an ONO structure including a silicon nitride layer 140 sandwiched between silicon dioxide layers 132 and 134. Two bits of data are stored in the memory cell 100 as charges that are trapped in charge-trapping regions 140A and 140B in the silicon nitride layer 140. Each region 140A or 140B corresponds to a bit having a value 0 or 1 according to the state of the trapped charges at the region 140A and 140B.

The memory cell 100 has the advantage of providing non-volatile storage of two bits of information in a single-transistor memory cell, increasing the storage density over that of a memory device storing one bit of data per storage transistor. However, scaling the memory cell 100 down to smaller sizes may present difficulties. In particular, operation of the memory cell 100 requires the ability to inject charges into separate regions 140A and 140B in the silicon nitride layer 140. As the width of the silicon nitride layer 140 decreases, the distance between locations 140A and 140B may become too small, which could result in merging of the regions 140A and 140B.

### SUMMARY OF THE INVENTION

One aspect of the present invention provides a multi-level flash memory structure and method for preparing the same with the storage structures separated by a protrusion to prevent the storage structures from being merged as the size of the flash memory is reduced.

A multi-level flash memory structure according to this aspect of the present invention comprises a semiconductor substrate having a protrusion, a plurality of storage structures separated by the protrusion, a dielectric layer overlying the storage structures and the protrusion of the semiconductor substrate, a gate structure positioned on the dielectric layer, and a plurality of diffusion regions positioned at the sides of the protrusion. Each of the storage structures includes a charge-trapping site and an insulation structure isolating the charge-trapping site from the semiconductor substrate.

As the size of the flash memory is reduced, the distance between the charge-trapping regions of the conventional flash memory may become too small, which in the prior art may result in merging of the charge-trapping regions. In contrast, the storage structures of the present invention are separated by the protrusion of the semiconductor substrate; therefore, the storage structures are prevented from merging, even as the size of the flash memory is reduced.

Another aspect of the present invention provides a method for preparing a multi-level flash memory structure comprising the steps of forming a protrusion in a semiconductor substrate, forming a plurality of storage structures at the sides of the protrusion, forming a dielectric layer overlying the storage structures and the protrusion of the semiconductor substrate, forming a gate structure on the dielectric layer, and forming a plurality of diffusion regions at the sides of the protrusion. Each of the storage structures includes a charge-trapping site and an insulation structure isolating the charge-trapping site from the semiconductor substrate.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 10 illustrate a method for preparing a multi-level flash memory structure according to one embodiment of the present invention;

FIG. 11 to FIG. 20 illustrate a method for preparing a multi-level flash memory structure according to another embodiment of the present invention; and

FIG. 21 shows a memory cell according to the prior art.

### DETAILED DESCRIPTION OF THE INVENTION

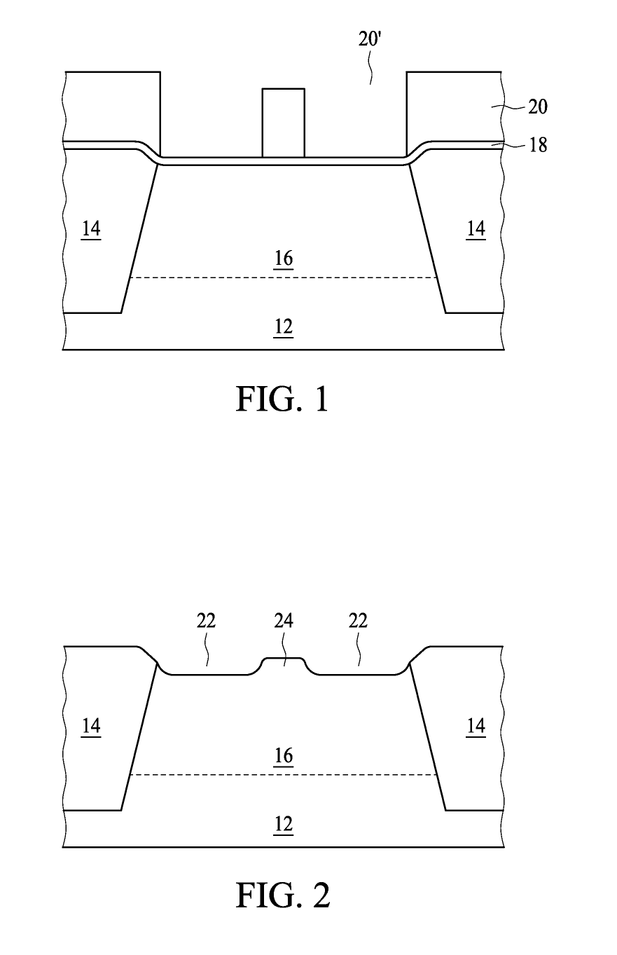

FIG. 1 to FIG. 10 illustrate a method for preparing a multi-level flash memory structure 10 according to one embodiment of the present invention. A lithographic process is performed to form a photoresist layer 20 on an anti-reflection layer 18 on a semiconductor substrate 12 such as a P-type silicon substrate with a shallow trench isolation (STI) 14 and a P-well 16 in the STI 14. The photoresist layer 20 has several openings 20′ exposing a portion of the P-well 16 of the semiconductor substrate 12. Subsequently, a dry etching process is then performed by using the photoresist layer 20 as an etching mask to remove a portion of the anti-reflection layer 18 and the P-well 16 under the opening 20′ of the photoresist layer 20 to form several depressions 22 in an upper portion of the semiconductor substrate 12, with a protrusion 24 between the several depressions 22 in the semiconductor substrate 12, and the anti-reflection layer 18 and the photoresist layer 20 are then removed, as shown in FIG. 2.

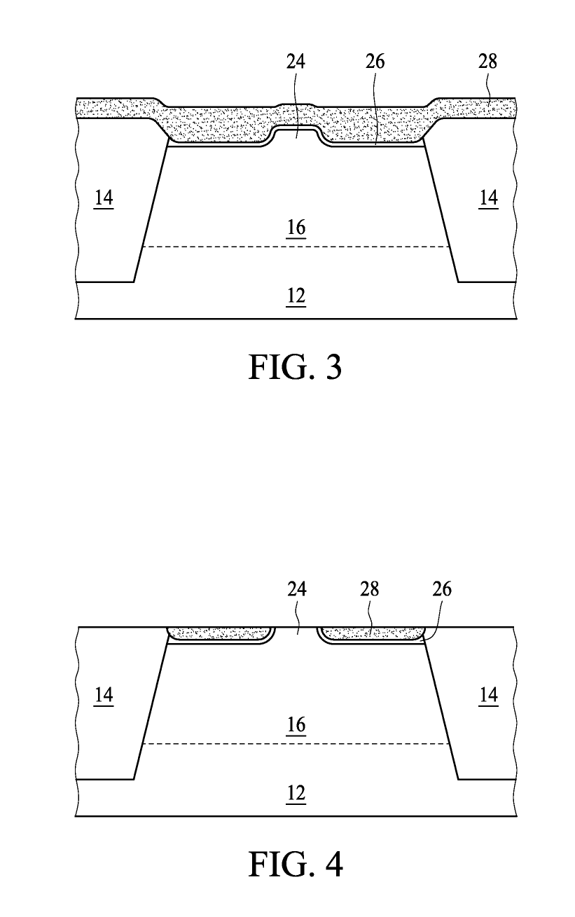

Referring to FIG. 3, a thermal oxidation process is performed to form an insulation structure 26 such as a silicon oxide layer serving as the gate oxide on the surface of the semiconductor substrate 12 and on the inner sidewall of the depressions 22, and a deposition process is then performed to form a charge-trapping layer 28 on the insulation structure 26 and filling the depressions 22. The charge-trapping layer 28 may include silicon nitride or polysilicon. Subsequently, a planarization process such as the chemical-mechanical polishing process (CMP) is performed to remove a portion of the charge-trapping layer 28 above the protrusion 24, as shown in FIG. 4.

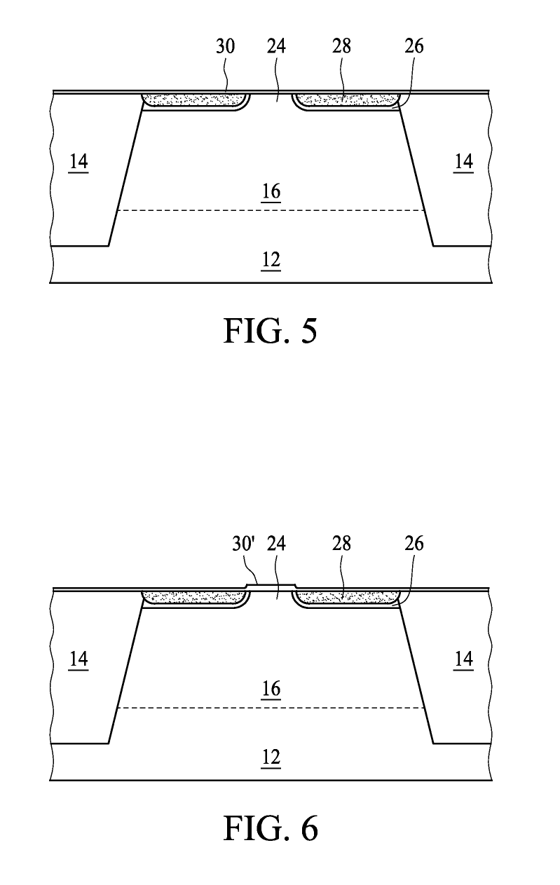

Referring to FIG. 5, an oxidation process such as an in-situ steam generation (ISSG) process is performed to form a dielectric layer 30 such as a silicon-oxy-nitride layer overlying the protrusion 24 of the semiconductor substrate 12 and the charge-trapping layer 28 in the depressions 22, with thickness of the dielectric layer 30 substantially uniform. In addition, the oxidation process can be a thermal oxidation process, which forms a dielectric layer 30′ such as silicon oxide layer overlying the protrusion 24 of the semiconductor substrate 12, with the thickness of the dielectric layer 30′ substantially larger on the protrusion 24 than on the charge-trapping layer 28, as shown in FIG. 6.

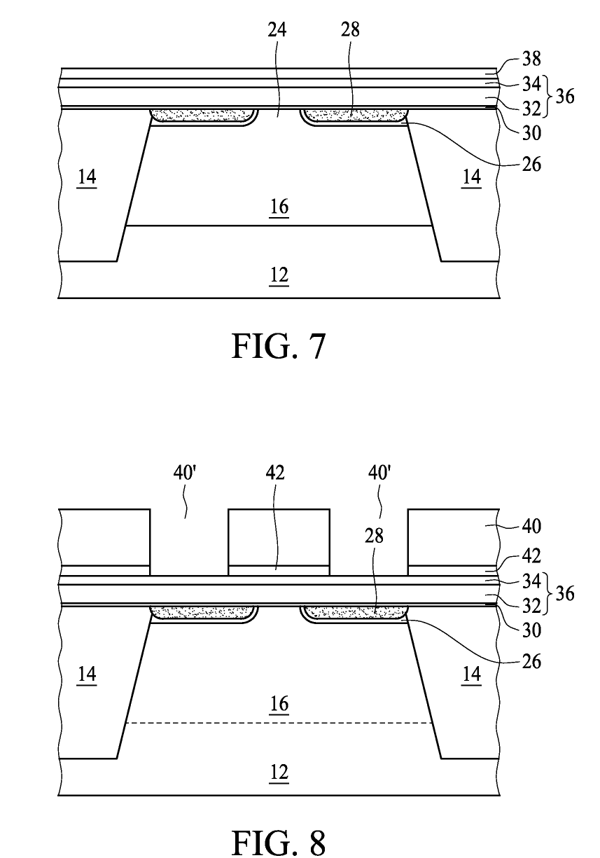

Referring to FIG. 7, deposition processes are performed on the dielectric layer 30 in FIG. 5 to form a gate stack 36 including a polysilicon layer 32 doped with N-type dopants and a metal silicide layer 34 such as tungsten silicide layer on the dielectric layer 30, and a silicon nitride layer 38 is then formed on the gate stack 36 by the deposition process. In particular, if the deposition processes are performed on the dielectric layer 30′ in FIG. 6, the gate stack 36 is formed on the charge-trapping layer 28 and the dielectric layer 30′. Subsequently, a photoresist layer 40 having a plurality of openings 40′ is formed on the silicon nitride layer 38 by the lithographic process, and a dry etching process is then performed by using the photoresist layer 40 as an etching mask to remove a portion of the silicon nitride layer 38 under the openings 40′ of the photoresist layer 40 to form a hard mask 42 on the gate stack 36, as shown in FIG. 8.

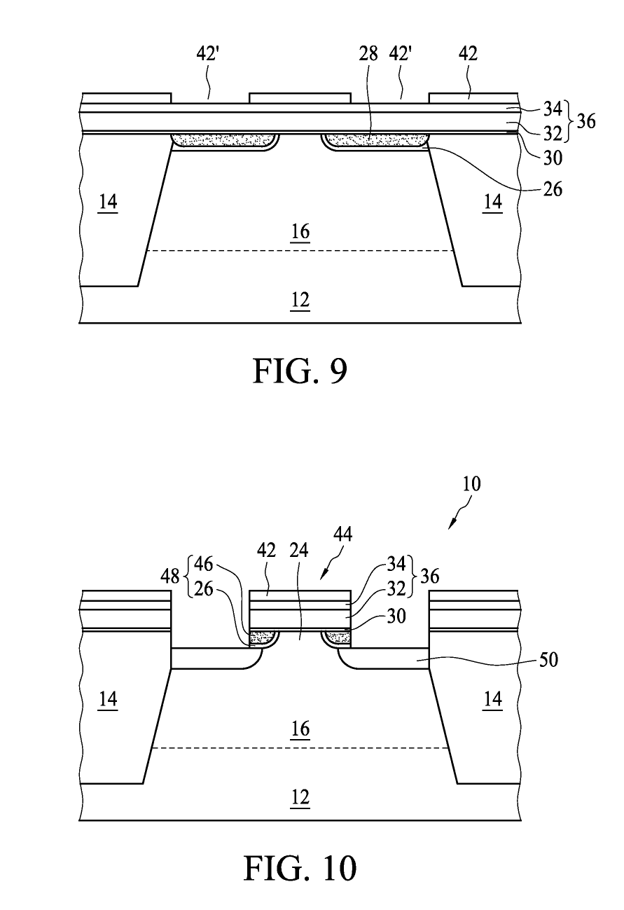

Referring to FIG. 9, the photoresist layer 40 is stripped, and the hard mask 42 has a plurality of openings 42′ on the gate stack 36; in particular, the hard mask 42 covers a portion of the charge-trapping layer 28 in the depressions 22, while the openings 42′ are directly on a portion of the charge-trapping layer 28 in the depressions 22. Subsequently, an anisotropic etching process such as the dry etching process is then performed to remove a portion of the gate stack 36, the dielectric layer 30 and the charge-trapping layer 28 directly below the openings 42′ of the hard mask 42 to form a gate structure 44 on the dielectric layer 30 and several storage structures 48, and an implanting process is then performed to form several diffusion regions 50 at the sides of the protrusion 24 in the semiconductor substrate 12 to complete the multi-level flash memory structure 10, as shown in FIG. 10.

The dry etching process also removes a portion of the charge-trapping layer 28 and the insulation structure 26 under the openings 42′ to form the storage structures 48 separated by the protrusion 24. The storage structures 48 are fan-shaped and include the charge-trapping sites 46 and the insulation structure 26 isolating the charge-trapping sites 46 from the semiconductor substrate 12. In particular, the diffusion regions 50 are positioned in the semiconductor substrate 12 and below the charge-trapping sites 46.

Furthermore, the upper end of the diffusion regions 50 is lower than the upper end of the shallow trench isolation 14, and the upper end of the charge-trapping sites 46 aligns with the upper end of shallow trench isolation 14. In addition, the charge-trapping site 46 is positioned in the semiconductor substrate 12, and the dielectric layer 30 overlies the storage structures 48. The multi-level flash memory structure 10 can use channel hot electron injection (CHEI) mechanism to conduct the programming of the cell, use the band-to-band (BTBT) hot hole enhanced injection (HHEI) mechanism to conduct the erasing of the cell, and use the reversed read mechanism to conduct the reading of the cell.

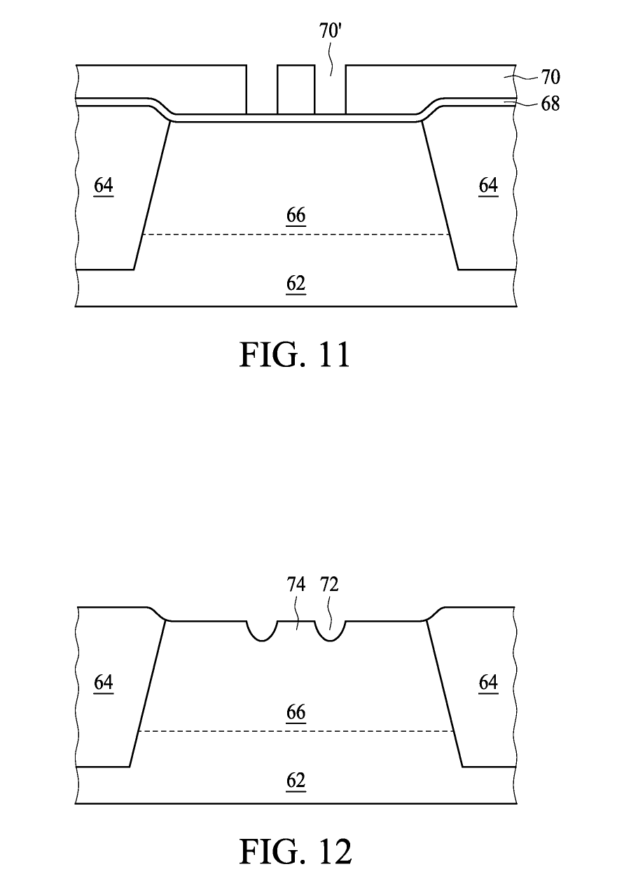

FIG. 11 to FIG. 20 illustrate a method for preparing a multi-level flash memory structure 60 according to one embodiment of the present invention. A lithographic process is performed to form a photoresist layer 70 on an anti-reflection layer 68 on a semiconductor substrate 62 such as a P-type silicon substrate with a shallow trench isolation (STI) 64 and a P-well 66 in the STI 64, and the photoresist layer 70 has a plurality of openings 70′ exposing a portion of the P-well 66 of the semiconductor substrate 62. Subsequently, a dry etching process is then performed by using the photoresist layer 70 as an etching mask to remove a portion of the anti-reflection layer 68 and the P-well 66 under the opening 70′ of the photoresist layer 70 to form several depressions 72 in an upper portion of the semiconductor substrate 62, with a protrusion 74 between the depressions 72 in the semiconductor substrate 62, and the anti-reflection layer 68 and the photoresist layer 70 are then removed, as shown in FIG. 12.

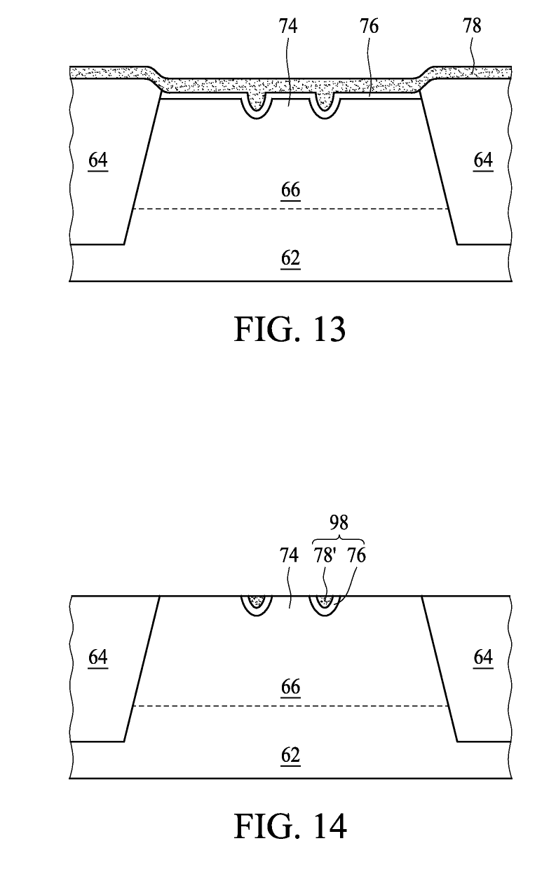

Referring to FIG. 13, a thermal oxidation process is performed to form an insulation structure 76 such as a silicon oxide layer serving as the gate oxide on the surface of the semiconductor substrate 72 and on the inner sidewall of the depressions 72, and a deposition process is then performed to form a charge-trapping layer 78 on the insulation structure 76 and filling the depressions 72. Subsequently, a planarization process such as the chemical-mechanical polishing process is performed to remove a portion of the charge-trapping layer 78 above the protrusion 74 so as to form several fan-shaped charge-trapping sites 78′ in the depressions 72 at the sides of the protrusion 74, as shown in FIG. 14. The planarization process results in several storage structures 98 separated by the protrusion 74 and consisting of the charge-trapping site 78′ and the insulation structure 76 isolating the charge-trapping site 78′ from the semiconductor substrate 62.

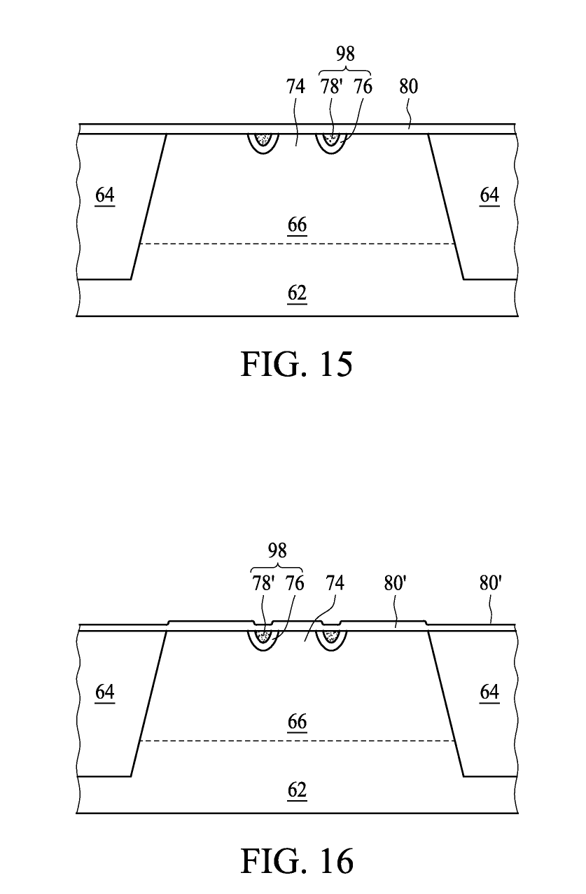

Referring to FIG. 15, an oxidation process such as an in-situ steam generation (ISSG) process is performed to form a dielectric layer 80 such as silicon-oxy-nitride layer overlying the storage structures 98 and the protrusion 74 of the semiconductor substrate 62, with thickness of the dielectric layer 80 substantially uniform. In addition, the oxidation process can be a thermal oxidation process, which forms a dielectric layer 80′ overlying the storage structures 98 and the protrusion 74 of the semiconductor substrate 62, with the thickness of the dielectric layer 80′ substantially larger on the protrusion 74 than on the charge-trapping site 78′, as shown in FIG. 16.

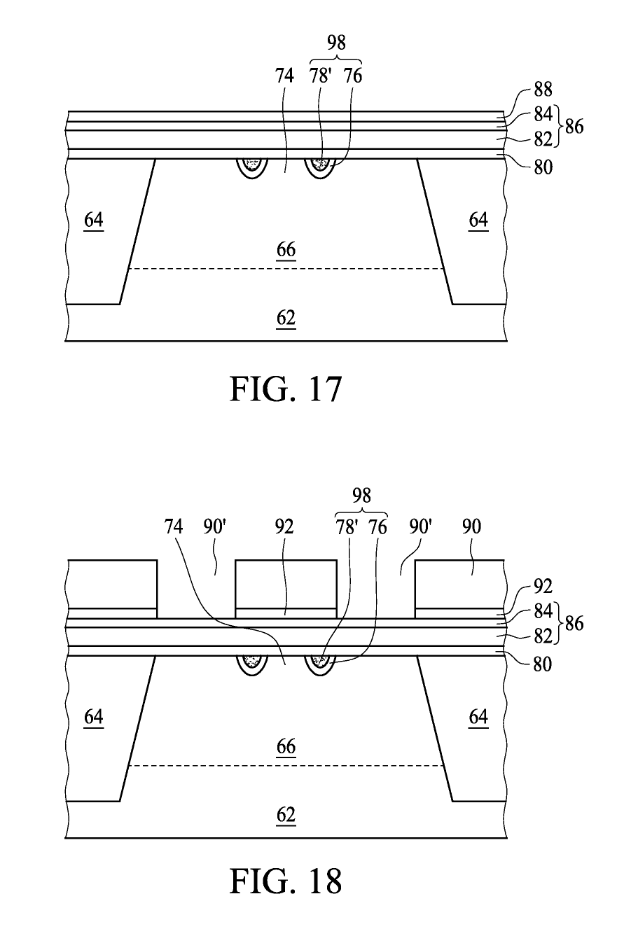

Referring to FIG. 17, deposition processes are performed on the dielectric layer 80 in FIG. 15 to form a gate stack 86 including a polysilicon layer 82 doped with N-type dopants and metal silicide layer 84 such as tungsten silicide layer on the dielectric layer 80, and a silicon nitride layer 88 is then formed on the gate stack 36 by the deposition process. Subsequently, a photoresist layer 90 having a plurality of openings 90′ is formed on the silicon nitride layer 88 by the lithographic process, and a dry etching process is then performed to remove a portion of the silicon nitride layer 88 under the openings 90′ of the photoresist layer 90 to form a hard mask 92 on the gate stack 86, as shown in FIG. 18.

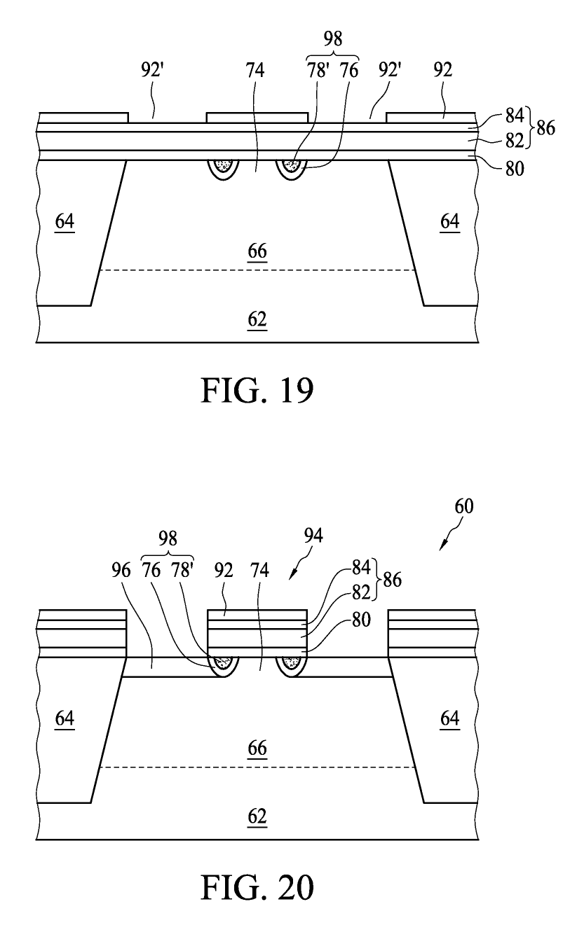

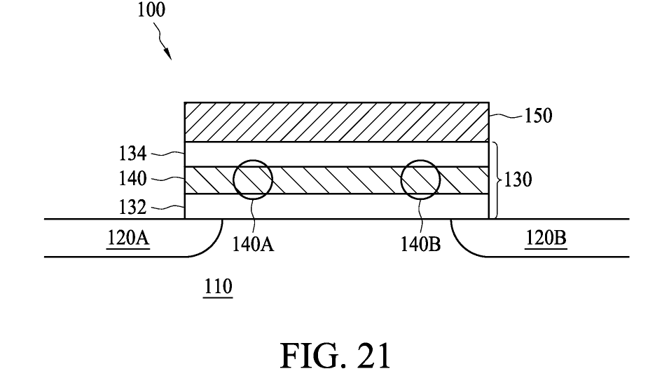

Referring to FIG. 19, the photoresist layer 90 is stripped, and the hard mask 92 has a plurality of openings 92′ on the gate stack 86; in particular, the openings 92′ are not on the charge-trapping sites 78′ but at the sides of the charge-trapping sites 78′. An anisotropic etching process such as the dry etching process is performed to remove a portion of the gate stack 86 directly under the openings 92′ of the hard mask 92 to form a gate structure 94. Subsequently, an implanting process is performed to form several diffusion regions 96 in the semiconductor substrate 62 at the sides of the charge-trapping sites 78′ to complete the multi-level flash memory structure 60.

In particular, the upper end of the charge-trapping site 78′ aligns with the upper end of the shallow trench isolation 64, and the upper end of the diffusion regions 96 aligns with the upper end of the shallow trench isolation 64 as well. The multi-level flash memory 60 can use channel hot electron injection (CHEI) mechanism to conduct the programming of the cell, use the band-to-band (BTBT) hot hole enhanced injection (HHEI) mechanism to conduct the erasing of the cell, and use the reversed read mechanism to conduct the reading of the cell.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A multi-level flash memory structure, comprising:
a semiconductor substrate having a protrusion;
a plurality of storage structures separated by the protrusion, with each of the storage structures including a charge-trapping site and an insulation structure isolating the charge-trapping site from the semiconductor substrate;
a dielectric layer overlying the storage structure and the protrusion of the semiconductor substrate;
a gate structure positioned on the dielectric layer; and
a plurality of diffusion regions positioned at the sides of the protrusion in the semiconductor substrate.

2. The multi-level flash memory structure of claim 1, wherein the semiconductor substrate includes a well, and the charge-trapping site is positioned in the well.

3. The multi-level flash memory structure of claim 1, wherein the charge-trapping site includes silicon nitride or polysilicon.

4. The multi-level flash memory structure of claim 1, wherein the insulation structure includes silicon oxide.

5. The multi-level flash memory structure of claim 1, wherein the dielectric layer includes silicon-oxy-nitride or silicon oxide.

6. The multi-level flash memory structure of claim 1, wherein the charge-trapping site is fan-shaped.

7. The multi-level flash memory structure of claim 1, wherein the thickness of the dielectric layer is substantially uniform.

8. The multi-level flash memory structure of claim 1, wherein the thickness of the dielectric layer is substantially larger on the protrusion than on the charge-trapping site.

9. The multi-level flash memory structure of claim 1, wherein the semiconductor substrate includes a plurality of depressions with the protrusion between the depressions, and the storage structures are positioned in the depressions.

10. The multi-level flash memory structure of claim 1, wherein the diffusion regions are positioned in the semiconductor substrate and below the charge-trapping site.

11. The multi-level flash memory of claim 1, wherein the diffusion regions are positioned at the sides of the protrusion.

12. The multi-level flash memory of claim 1, further comprising a shallow trench isolation, wherein the upper ends of the diffusion regions are lower than the upper end of the shallow trench isolation.

13. The multi-level flash memory of claim 1, further comprising a shallow trench isolation, wherein the upper end of the charge-trapping site aligns with the upper end of the shallow trench isolation.

14. The multi-level flash memory of claim 1, further comprising a shallow trench isolation, wherein the upper ends of the diffusion regions align with the upper end of the shallow trench isolation.

15. The multi-level flash memory of claim 1, wherein the charge-trapping site is positioned in the semiconductor substrate.
